(19) United States
(12) Patent Application Publication
(10) Pub. No.: US 2026/0047195 A1
(43) Pub. Date: Feb. 12, 2026

(54) NANOSHEET TRANSISTORS WITH LEVEL-TO-LEVEL GATE STRAPPING

(71) Applicant: International Business Machines Corporation, Armonk, NY (US)

(72) Inventors: Brent Alan Anderson, Jericho, VT (US); Ruilong Xie, Niskayuna, NY (US); Albert Manhee Chu, Nashua, NH (US); David Wolpert, Poughkeepsie, NY (US); Nicholas Anthony Lanzillo, Wynantskill, NY (US); Lawrence Alfred Clevenger, Saratoga Springs, NY (US)

(21) Appl. No.: 18/678,123

(22) Filed: May 30, 2024

(51) Int. Cl. H10D 84/85; H10D 30/00; H10D 30/01; H10D 30/43; H10D 62/10; H10D 84/01

(52) U.S. Cl. CPC H10D 84/852; H10D 30/43; H10D 30/502; H10D 62/121; H10D 30/014; H10D 30/019; H10D 84/0172

(57) ABSTRACT

A semiconductor device comprises a plurality of channel layers in a stacked configuration, and a gate structure disposed through respective ones of the plurality of channel layers. The gate structure is surrounded on at least three sides by portions of the respective ones of the plurality of channel layers. The gate structure is disposed from an uppermost channel layer of the plurality of channel layers to a lowermost channel layer of the plurality of channel layers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide structures for and techniques for forming nanosheet field-effect transistors (FETs) with level-to-level gate strapping.

In one embodiment, a semiconductor device comprises a plurality of channel layers in a stacked configuration, and a gate structure disposed through respective ones of the plurality of channel layers.

In another embodiment, a semiconductor device comprises a plurality of channel layers alternately stacked with first portions of a gate structure, and a second portion of the gate structure disposed through respective ones of the plurality of channel layers.

In another embodiment, a nanosheet transistor comprises a plurality of channel layers in a stacked configuration, and a gate structure disposed between respective first portions of the plurality of channel layers on a first side of the gate structure and respective second portions of the plurality of channel layers on a second side of the gate structure. The gate structure is disposed from an uppermost channel layer of the plurality of channel layers to a lowermost channel layer of the plurality of channel layers.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with line Y on which the cross-sectional views of FIGS. 2 and 3 are based, according to an embodiment of the invention.

FIG. 2 depicts a cross-sectional view corresponding to the line Y in FIG. 1 illustrating patterned nanosheet layers with dielectric layers between the patterned nanosheet layers, according to an embodiment of the invention.

FIG. 3 depicts a cross-sectional view corresponding to the line Y in FIG. 1 following hardmask removal from the structure of FIG. 2, according to an embodiment of the invention.

FIG. 4 depicts a top view of a semiconductor structure with lines X and Y on which the cross-sectional views of FIGS. 5, 6, 7 and 8 are based, according to an embodiment of the invention.

FIG. 5 depicts a first cross-sectional view corresponding to the line X in FIG. 4 following dummy gate formation, nanosheet recessing, inner spacer formation and source/drain region formation, according to an embodiment of the invention.

FIG. 6 depicts a second cross-sectional view corresponding to the line Y in FIG. 4 following dummy gate formation, nanosheet recessing, inner spacer formation and source/drain region formation, according to an embodiment of the invention.

FIG. 7 depicts a first cross-sectional view corresponding to the line X in FIG. 4 following inter-layer dielectric (ILD) layer formation, according to an embodiment of the invention.

FIG. 8 depicts a second cross-sectional view corresponding to the line Y in FIG. 4 following ILD layer formation, according to an embodiment of the invention.

FIG. 9 depicts a top view of a semiconductor structure with lines X and Y on which the cross-sectional views of FIGS. 10 and 11 are based, according to an embodiment of the invention.

FIG. 10 depicts a first cross-sectional view corresponding to the line X in FIG. 9 following dummy gate removal, according to an embodiment of the invention.

FIG. 11 depicts a second cross-sectional view corresponding to the line Y in FIG. 9 following dummy gate removal, according to an embodiment of the invention.

FIG. 12 depicts a top view of a semiconductor structure with lines X and Y on which the cross-sectional views of FIGS. 13, 14, 15 and 16 are based, according to an embodiment of the invention.

FIG. 13 depicts a first cross-sectional view corresponding to the line X in FIG. 12 following patterning of openings through portions of the nanosheet stacks, according to an embodiment of the invention.

FIG. 14 depicts a second cross-sectional view corresponding to the line Y in FIG. 13 following patterning of openings through portions of the nanosheet stacks, according to an embodiment of the invention.

FIG. 15 depicts a first cross-sectional view corresponding to the line X in FIG. 12 following removal of sacrificial semiconductor layers, according to an embodiment of the invention.

FIG. 16 depicts a second cross-sectional view corresponding to the line Y in FIG. 12 following removal of sacrificial semiconductor layers, according to an embodiment of the invention.

FIG. 17 depicts a top view of a semiconductor structure with lines X and Y on which the cross-sectional views of FIGS. 18 and 19 are based, according to an embodiment of the invention.

FIG. 18 depicts a first cross-sectional view corresponding to the line X in FIG. 17 following replacement gate structure and middle-of-line (MOL) contact formation, according to an embodiment of the invention.

FIG. 19 depicts a second cross-sectional view corresponding to the line Y in FIG. 17 following replacement gate structure and MOL contact formation, according to an embodiment of the invention.

FIG. 20 depicts a top view of a semiconductor structure with line X on which the cross-sectional view of FIG. 21 is based, according to an embodiment of the invention.

FIG. 21 depicts a cross-sectional view corresponding to the line X in FIG. 20 illustrating a semiconductor structure with a gate structure through portions of nanosheet channel layers, according to an embodiment of the invention.

### DETAILED DESCRIPTION

Illustrative embodiments of the invention may be described herein in the context of illustrative methods for forming nanosheet FETs with level-to-level gate strapping, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration. ” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

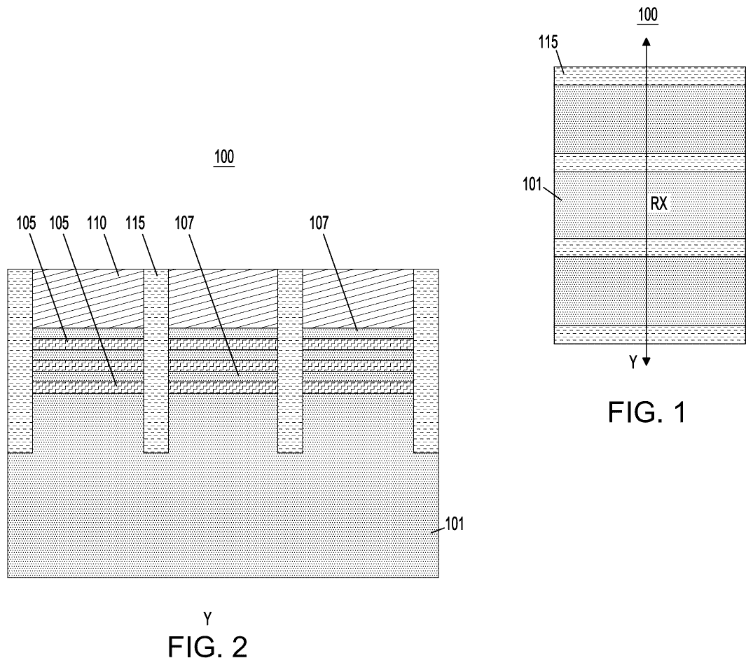

FIG. 1 depicts a top view of a semiconductor structure 100 with line Y on which the cross-sectional views of FIGS. 2 and 2 are based. FIG. 1 illustrates active regions (Rx) on a semiconductor substrate 101 and dielectric layers 115. FIG. 2 illustrates the semiconductor structure 100 with patterned nanosheet layers and the dielectric layers 115 between the patterned nanosheet layers.

In more detail, referring to FIGS. 1 and 2, a semiconductor structure 100 includes a stacked structure of sacrificial layers 105 and channel layers 107. In an illustrative embodiment, the sacrificial layers 105 comprise silicon germanium (SiGe) and the channel layers 107 comprise silicon. In illustrative embodiments, the sacrificial layers 105 comprise a germanium concentration of about 30% (e.g., SiGe30), but the embodiments are not necessarily limited to SiGe30 for the sacrificial layers 105. The semiconductor substrate 101 comprises semiconductor material including, but not limited to, silicon, III-V, II-V compound semiconductor materials or other like semiconductor materials. In addition, multiple layers of the semiconductor materials can be used as the semiconductor material of the semiconductor substrate 101.

The sacrificial layers 105 and channel layers 107 are epitaxially grown in an alternating and stacked configuration on the semiconductor substrate 101. In either case, a first sacrificial layer 105 is followed by a first channel layer 107 on the first sacrificial layer 105, which is followed by a second sacrificial layer on the first channel layer 107, and so on. As can be understood, the sacrificial and channel layers 105 and 107 are epitaxially grown from their corresponding underlying semiconductor layers.

While three sacrificial layers 105 and three channel layers 107 are shown, the embodiments of the present invention are not necessarily limited to the shown number of sacrificial and channel layers 105 and 107, and there may be more or less layers in the same alternating configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height (vertical direction in FIG. 2) of the sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In a non-limiting illustrative embodiment, a length (horizontal direction in FIG. 2) of the sacrificial layers 105 and of the channel layers 107 can be greater than about 20 nm or greater than about 40 nm. In accordance with an embodiment of the present invention, each of the channel layers 107 has the same or substantially the same composition and size as each other, and each of the sacrificial layers 105 has the same or substantially the same composition and size as each other.

As can be seen in FIG. 2, portions of the nanosheet stacks comprising the sacrificial layers 105 and channel layers 107 are covered with hardmask layers 110. The hardmask layers 110 comprise, for example, a nitride such as silicon nitride (SiN) or other nitride material. Portions of the nanosheet stacks which are not under the hardmask layers 110 are removed and underlying portions of the semiconductor substrate 101 are recessed. Dielectric layers 115 in, for example, a columnar or bar shape, are deposited between remaining portions of the nanosheet stacks and in the recessed portions of the semiconductor substrate 101. The material of the dielectric layers 115 may comprise, for example, silicon oxide (SiOₓ) (where x is for example, 2, 1.99 or 2.01), silicon oxycarbide (SiOC) or other dielectric material that will permit selective removal of the hardmask layers 110. In illustrative embodiments, a thickness (e.g., in the horizontal direction in FIG. 2) of the dielectric layers 115 is greater than about 5 nm.

In other parts of the semiconductor structure 100, isolation regions (e.g., shallow trench isolation (STI) regions) (not shown) are formed between remaining nanosheet stacks in recessed portions of the semiconductor substrate 101. The isolation regions comprise dielectric material such as, for example, SiN, silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof. The dielectric layers 115 and the dielectric material of the isolation regions can be deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). A planarization process such as, for example, chemical mechanical planarization (CMP) can be performed to planarize the dielectric layers 115 following their deposition.

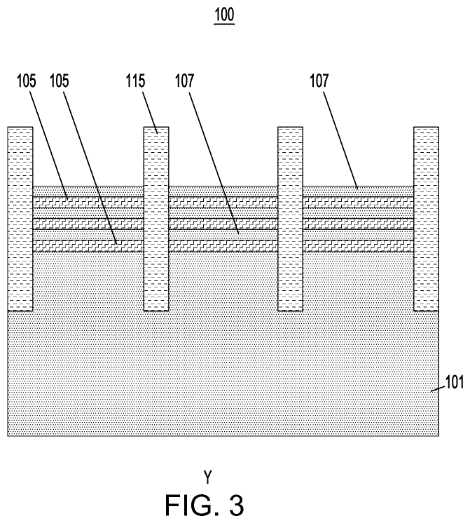

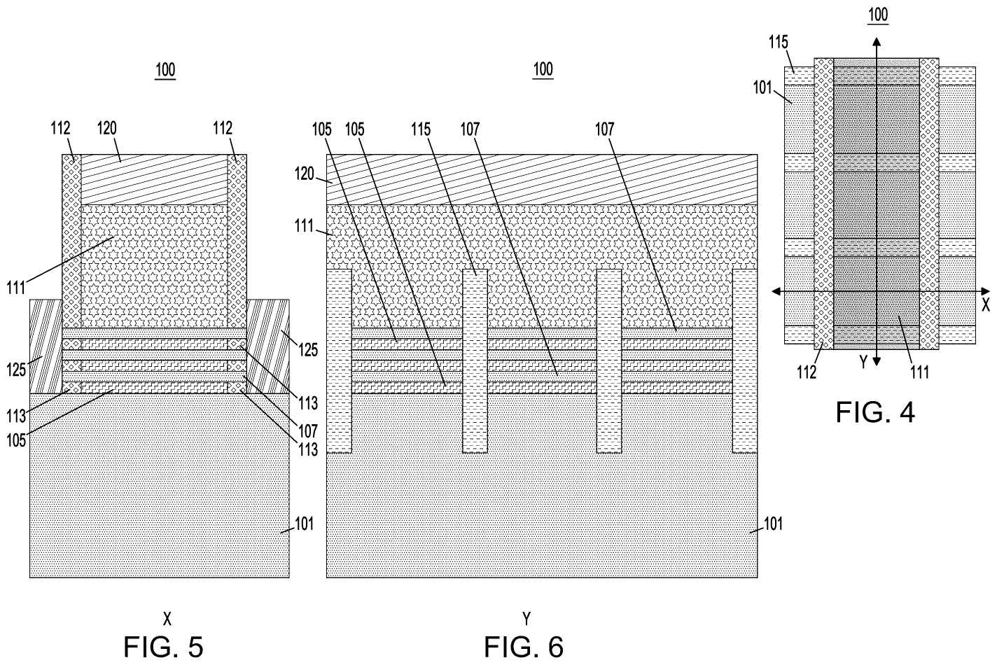

Referring to FIG. 3, the hardmask layers 110 are selectively removed with respect to the dielectric layers 115. Then, referring to FIGS. 4-6, dummy gate portions 111 are formed on the uppermost channel layers 107 and around the stacked nanosheet configurations of the sacrificial layers 105 and channel layers 107. The dummy gate portions 111 are further formed on and around the dielectric layers 115. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process such as CMP, and lithography and etching steps to remove excess dummy gate material, and pattern the deposited layer. Hardmask layers 120 are formed on the dummy gate portions 111. Like the hardmask layers 110, the hardmask layers 120 comprise, for example, a nitride such as SiN or other nitride material.

Gate spacers 112 are formed on sides of the hardmask layers 120 and dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

Exposed portions of the stacked sacrificial layers 105 and channel layers 107, which are not under the hardmask layers 120, gate spacers 112 and dummy gate portions 111, are removed using, for example, an etching process, such as RIE, where the hardmask layers 120, gate spacers 112 and dummy gate portions 111 are used as a mask. The portions of the stacked structures of sacrificial layers 105 and channel layers 107 under the hardmask layers 120, gate spacers 112 and under the dummy gate portions 111 remain after the etching process, and portions of the sacrificial layers 105 and channel layers 107 in areas that correspond to where source/drain regions 125 will be formed are removed.

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

In accordance with an illustrative embodiment, epitaxial source/drain regions 125 (“source/drain regions 125”) are grown from exposed side surfaces of the channel layers 107. Side surfaces of respective ones of the channel layers 107 contact side surfaces of the adjacent source/drain regions 125. The top surfaces of the source/drain regions 125 are above the top surfaces of uppermost ones of the channel layers 107.

According to a non-limiting embodiment of the present invention, the conditions of the epitaxial growth process for the source/drain regions 125 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the source/drain regions 125 can comprise silicon doped with n-type dopants including, for example, phosphorus (P), arsenic (As) and antimony (Sb). In the case of p-type FETS (pFETs), the source/drain regions 125 can comprise silicon doped with n-type dopants including, for example, boron (B), boron fluoride (BF₂), gallium (Ga), indium (In), and thallium (Tl).

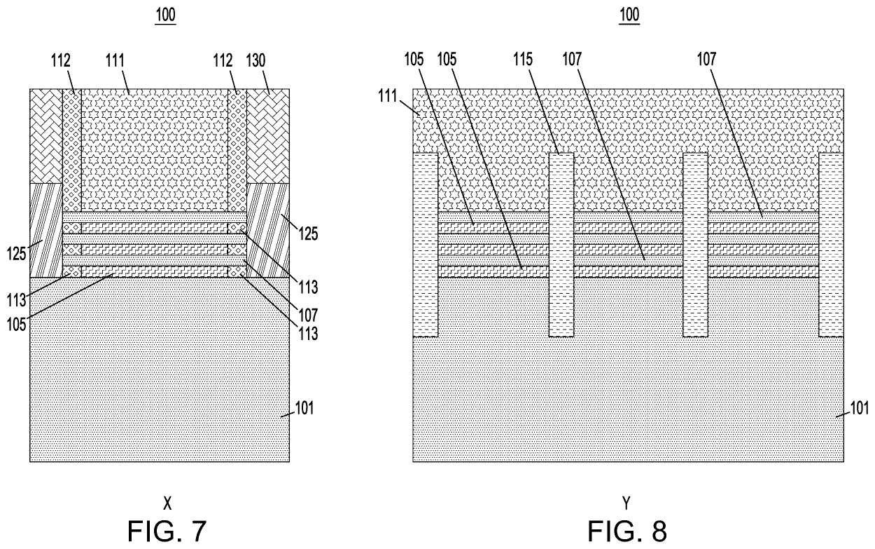

Referring to FIGS. 7 and 8, an inter-layer dielectric (ILD) layer 130 is deposited to fill in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may comprise, for example, SiOₓ, SiOC, SiOCN or some other dielectric.

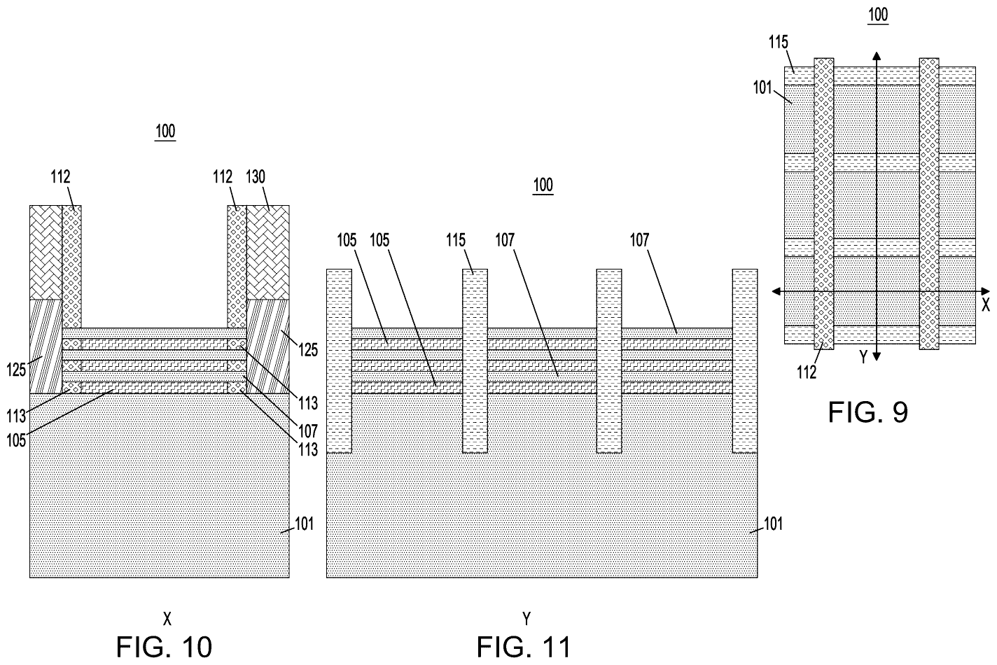

Referring to FIGS. 9-11, the dummy gate portions 111 are selectively removed to create vacant areas where gate structures will be formed in place of the dummy gate portions 111. The selective removal can be performed using, for example, hot ammonia to remove a-Si. As can be seen, the removal of the dummy gate portions 111 exposes the uppermost channel layers 107 of the nanosheet stacks.

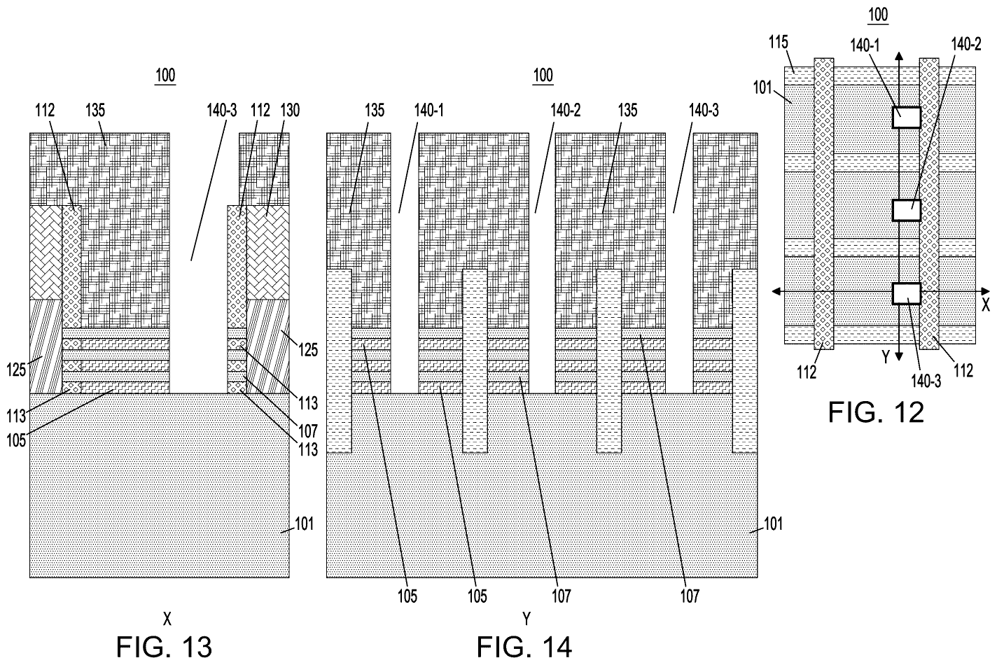

Referring to FIGS. 12-14, portions of the exposed nanosheet stacks are removed to form openings 140-1, 140-2 and 140-3 (collectively “openings 140”) through portions of the nanosheet stacks. In more detail, organic planarization layers (OPLs) 135 are formed on portions of the nanosheet stacks comprising the channel layers 107 and sacrificial layers 105, on portions of the gate spacers 112, on the ILD layer 130 and on the dielectric layers 115. Portions of the nanosheet stacks are left exposed. The OPLs 135 comprise, but are not necessarily limited to, an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Non-limiting examples of the OPL material include JSR HM8006, JSR HM8014, AZ UM10M2, Shin Etsu ODL-102, or other similar commercially available materials from such vendors as JSR, TOK, Sumitomo, Rohm & Haas, etc. The OPLs 135 can be deposited, for example, by spin coating.

Exposed portions of the nanosheet stacks are removed down to the semiconductor substrate 101 to create the openings 140. As can be seen portions of the nanosheet stacks remain on lateral sides of each of the openings 140. The removal process for the exposed portions of the nanosheet stacks includes, for example, a dry etch process. The respective openings in each channel layer 107 of a stacked configuration are aligned with each other.

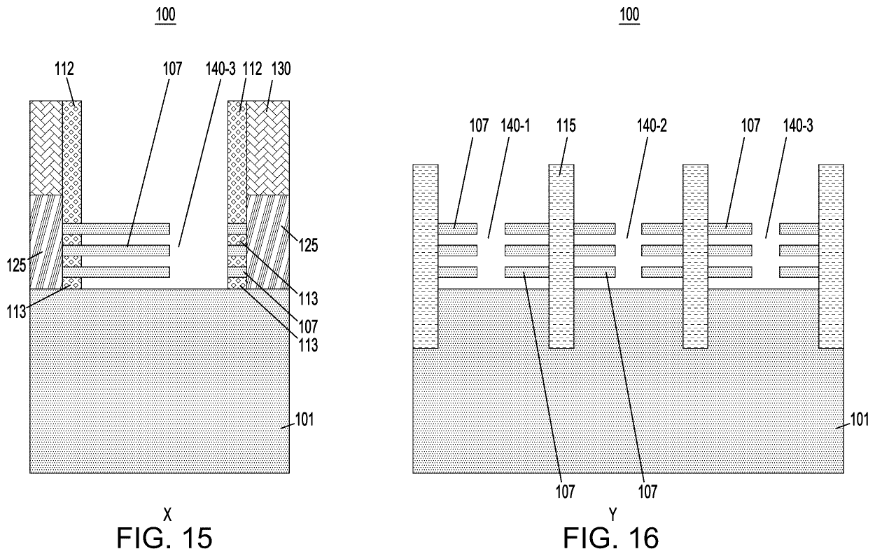

Referring to FIGS. 15 and 16, following removal of the exposed portions of the nanosheet stacks to create the openings 140, the OPLs 135 are stripped using, for example, oxygen plasma, nitrogen/hydrogen plasma or other carbon strip processes. OPL stripping causes minimal or no damage to exposed layers. In addition, the sacrificial layers 105 are selectively removed to create vacant areas where gate structures will be formed in place of the sacrificial layers 105. The sacrificial layers 105 are selectively removed with respect to the channel layers 107. The selective removal can be performed using, for example, a dry HCl etch.

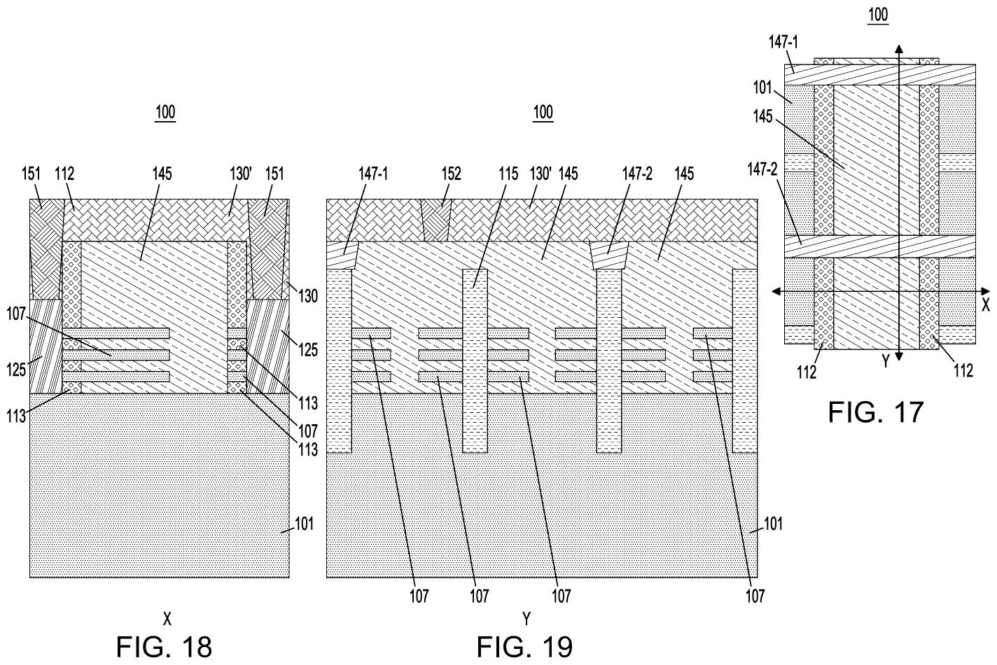

Referring to FIGS. 17-19, following removal of the dummy gate portions 111 and sacrificial layers 105, the channel layers 107 are suspended, and gate structures 145, including, for example, gate and dielectric portions, are formed filling in the openings 140 that were created by the removal of the exposed portions of the nanosheet stacks. The gate structures 145 further fill in vacant portions that were left by removal of the dummy gate portions 111 and the sacrificial layers 105. In illustrative embodiments, each gate structure 145 includes a gate dielectric layer such as, for example, a high-k dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 145 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Parts of the gate structures 145 above some of the dielectric layers 115 are removed down to top surfaces of the corresponding dielectric layers 115 to form trenches in which gate cut dielectric material is deposited to form gate cut portions 147-1 and 147-2 (collectively “gate cut portions 147”). The parts of the gate structures 145 are etched using, for example, RIE. The dielectric material of the gate cut portions 147 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the gate structures 145. The dielectric material of the gate cut portions 147 may comprise, but is not necessarily limited to, SiN, SiC, SiON, SiOC, SiCN, BN, SiBN, SiBCN, SiOCN, SiOₓ or some other dielectric.

Referring to FIGS. 18 and 19, additional ILD material is deposited to form an additional ILD layer 130′ on top of the ILD layer 130 and on top of the gate structures 145. Then, source/drain contacts 151 are formed in the ILD layers 130 and 130′. In forming the source/drain contacts 151, openings are formed through portions of the ILD layers 130 and 130′. The openings expose portions the source/drain regions 125 on which the source/drain contacts 151 are to be formed. According to an embodiment, masks are formed on parts of the additional ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF₃ based chemistry.

Metal layers are deposited in the openings to form the source/drain contacts 151. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

Respective ones of the source/drain contacts 151 contact respective ones of the source/drain regions 125. The source/drain contacts 151 extend through the ILD layers 130 and 130′ to land on and contact the corresponding source/drain regions 125.

At least one gate contact 152 is formed through the additional ILD layer 130′ to land on and contact a corresponding gate structure 145. The process and materials used for forming the gate contact 152 are similar to those used for forming the source/drain contacts 151.

As can be seen in FIGS. 18 and 19, the plurality of channel layers 107 are in stacked configurations, and portions of gate structures 145, which may be isolated from each other by dielectric layers 115 and gate cut portions 147, are disposed through respective ones of the plurality of channel layers 107. As can be seen in FIG. 18, parts of respective ones of a plurality of channel layers 107 in different stacked configurations contact an adjacent dielectric layer 115.

In illustrative embodiments, the gate structures 145 are disposed through inner portions of a group of channel layers 107 in a stacked configuration. Outer portions of the respective ones of the group of channel layers are disposed on sides of a gate structure 145. The gate structures 145 are disposed from an uppermost channel layer of a plurality of channel layers 107 to a lowermost channel layer of the plurality of channel layers 107. The gate structures 145 are surrounded on at least three sides by remaining portions of the respective ones of the plurality of channel layers 107. Portions of the gate structures 145 are further disposed between and alternately stacked with the respective ones of the plurality of channel layers 107.

As can be seen in FIG. 18, where the gate structure 145 is disposed through the channel layers 107, remaining portions of the respective channel layers 107 are disposed on sides of the gate structure 145 (e.g., left and right sides) between source/drain regions 125 (e.g., left and right source/drain regions) and the gate structure 145. In illustrative embodiments, an inner spacer 113 is disposed over and/or under at least part of remaining portions of the channel layer s107 disposed on the side of the gate structure 145.

As can be seen in FIGS. 18 and 19, portions of the gate structures 145 are disposed between respective first portions of the plurality of channel layers 107 on a first side (e.g., left side in FIGS. 18 and 19) of a gate structure 145 and respective second portions of the plurality of channel layers 107 on a second side (e.g., right side in FIGS. 18 and 19) of the gate structure 145. A width of the gate structure 145 between respective first and second portions of the plurality of channel layers 107 is less than half of a distance from the source/drain region 125 on a first side (e.g., left side in the drawings) of the stacked configuration of channel layers 107 to the source/drain region 125 on a second side (e.g., right side in the drawings) of the stacked configuration. In this case, width refers to a distance in a horizontal (e.g., left-right) direction in the drawings. As can be seen, the gate structure 145 disposed through the channel layers 107 is closer to the source/drain region 125 on the second (e.g., right) side which, in illustrative embodiments, functions as a drain of a FET, where the source/drain region 125 on the first (e.g., left) side functions as a source of a FET.

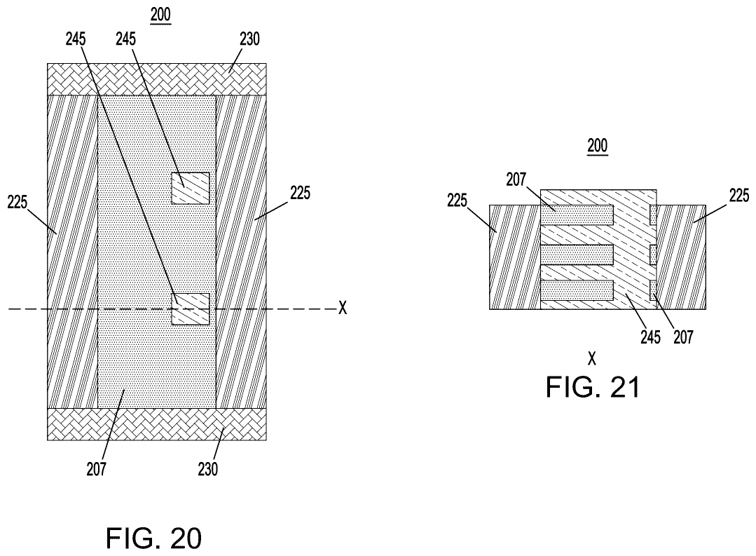

FIG. 20 depicts a top view of a semiconductor structure 200 with line X on which the cross-sectional view of FIG. 21 is based, and FIG. 21 depicts a cross-sectional view corresponding to the line X in FIG. 20 illustrating the semiconductor structure 200 with a gate structure 245 disposed through portions of channel layers 207. The semiconductor structure 200 is similar to the semiconductor structure 100, and certain elements (e.g., spacers) are not shown for purposes of simplicity of explanation. In addition, the same or similar elements to those in the semiconductor structure 100 have similar reference numerals. For example, the channel layers 207, source/drain regions 225, ILD layer 230 and gate structure 245 of the semiconductor structure 200 are the same as or similar to the channel layers 107, source/drain regions 125, ILD layer 130 and gate structures 145 of the semiconductor structure 100.

As can be seen in FIG. 21, the plurality of channel layers 207 are in a stacked configuration, and a portion of a gate structure 245 is disposed through respective ones of the plurality of channel layers 207. As can be seen in the top view of FIG. 20 and in the cross-sectional view of FIG. 21, the gate structure 245 is surrounded on at least three sides by remaining portions of the respective ones of the plurality of channel layers 207. For example, FIG. 20 shows the gate structure 245 surrounded on four sides by remaining portions of an uppermost channel layer 207.

The gate structure 245 is disposed through the stacked channel layers 207 from above an uppermost channel layer of the plurality of channel layers 207 to below a lowermost channel layer of the plurality of channel layers 207. Other portions of the gate structure 245 are further disposed between and alternately stacked with the respective ones of the plurality of channel layers 207.

As can be seen in FIGS. 20 and 21, where the gate structure 245 is disposed through the channel layers 207, remaining portions of the respective channel layers 207 are disposed on sides of the gate structure 245 (e.g., left and right sides) between source/drain regions 225 (e.g., left and right source/drain regions) and the gate structure 245. As can be seen in the top view of FIG. 20, each gate structure 245 does not extend to sides of the respective ones of the plurality of channel layers 207 in a top-down view. In other words, in the orientation shown in the top view of FIG. 20, each gate structure 245 extends partially in the horizontal direction between left and right sides of a channel layer 207 and extends partially in the vertical direction between top and bottom sides of a channel layer 207. For example, as shown in the top view of FIG. 20, the gate structures 245 do not reach left and right sides of the uppermost channel layer 207 and do not reach top and bottom sides of the uppermost channel layer 207.

As can be seen in FIG. 21, a portion of the gate structure 245 is disposed between respective first portions of the plurality of channel layers 207 on a first side (e.g., left side in FIG. 21) of the gate structure 245 and respective second portions of the plurality of channel layers 207 on a second side (e.g., right side in FIG. 21) of the gate structure 245. A width of the of the gate structure 245 between respective first and second portions of the plurality of channel layers 207 is less than half of a distance from the source/drain region 225 on a first side (e.g., left side in the drawings) of the stacked configuration of channel layers 207 to the source/drain region 225 on a second side (e.g., right side in the drawings) of the stacked configuration. In this case, width refers to a distance in a horizontal (e.g., left-right) direction in the drawings. As can be seen, the gate structure 245 disposed through the channel layers 207 is closer to the source/drain region 225 on the second (e.g., right) side which, in illustrative embodiments, functions as a drain of a FET, where the source/drain region 225 on the first (e.g., left) side functions as a source of a FET.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques to manufacture and structures for nanosheet FETs with level-to-level gate strapping. In the illustrative embodiments, as a result of a gate structure (e.g. gate structure 145/245) vertically extending through each of the nanosheet channel layers 107/207 there are multiple gate level-to-level connection points (e.g., each channel layer 107/207 being a level) in the same device. In addition, active channel layer ends are isolated by the dielectric layers 115. The illustrative embodiments advantageously improve density by eliminating extra track height for gate wrap around areas. In addition, long channel FETs (e.g., channel lengths greater than 20 nm or greater than 40 nm) have improved performance due to relatively large and low resistance source/drain regions. Also, the embodiments simplify n-type FET (nFET) and p-type FET (pFET) replacement metal gate (RMG) processes since gates are physically isolated by the dielectric layers 115.

In one embodiment, a semiconductor device comprises a plurality of channel layers in a stacked configuration, and a gate structure disposed through respective ones of the plurality of channel layers.

The gate structure may be surrounded on at least three sides by portions of the respective ones of the plurality of channel layers. The gate structure may be disposed from an uppermost channel layer of the plurality of channel layers to a lowermost channel layer of the plurality of channel layers. Portions of the gate structure may be further disposed between and alternately stacked with the respective ones of the plurality of channel layers.

The semiconductor device may further comprise a first source/drain region disposed on a first side of the plurality of channel layers and a second source/drain region disposed on a second side of the plurality of channel layers, wherein a width of the gate structure is less than half of a distance from the first source/drain region to the second source/drain region. The gate structure may be closer to one of the first source/drain region and the second source/drain region.

The semiconductor device may further comprise at least one source/drain region disposed on a side of the plurality of channel layers, wherein a portion of each of the respective ones of the plurality of channel layers is disposed on a side of the gate structure between the at least one source/drain region and the gate structure. The semiconductor device may further comprise a dielectric spacer disposed at least one of over and under at least part of the portion of each of the respective ones of the plurality of channel layers.

The gate structure may be disposed through an inner portion of each of the respective ones of the plurality of channel layers. Outer portions of the respective ones of the plurality of channel layers may be disposed on sides of the gate structure.

The semiconductor device may further comprise an additional plurality of channel layers in an additional stacked configuration disposed on a side of the plurality of channel layers, and a dielectric layer disposed between the plurality of channel layers and the additional plurality of channel layers. Parts of respective ones of the plurality of channel layers and parts of respective ones of the additional plurality of channel layers may contact the dielectric layer.

In another embodiment, a semiconductor device comprises a plurality of channel layers alternately stacked with first portions of a gate structure, and a second portion of the gate structure disposed through respective ones of the plurality of channel layers.

The second portion of the gate structure may be surrounded on at least three sides by portions of the respective ones of the plurality of channel layers. The second portion of the gate structure may be disposed from an uppermost channel layer of the plurality of channel layers to a lowermost channel layer of the plurality of channel layers.

The semiconductor device may further comprise at least one source/drain region disposed on a side of the plurality of channel layers, wherein a portion of each of the respective ones of the plurality of channel layers is disposed on a side of the second portion of the gate structure between the at least one source/drain region and the second portion of the gate structure.

The second portion of the gate structure may be disposed through an inner portion of each of the respective ones of the plurality of channel layers.

In another embodiment, a nanosheet transistor comprises a plurality of channel layers in a stacked configuration, and a gate structure disposed between respective first portions of the plurality of channel layers on a first side of the gate structure and respective second portions of the plurality of channel layers on a second side of the gate structure. The gate structure is disposed from an uppermost channel layer of the plurality of channel layers to a lowermost channel layer of the plurality of channel layers.

The gate structure may be surrounded on at least three sides by respective ones of the plurality of channel layers. Portions of the gate structure may be further disposed between and alternately stacked with respective ones of the plurality of channel layers. The nanosheet transistor of may further comprise at least one source/drain region disposed on a side of the stacked configuration, wherein the respective first portions of the plurality of channel layers and the respective second portions of the plurality of channel layers are disposed between the at least one source/drain region and the gate structure.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of channel layers in a stacked configuration; and
a gate structure disposed through respective ones of the plurality of channel layers.

2. The semiconductor device of claim 1, wherein the gate structure is surrounded on at least three sides by portions of the respective ones of the plurality of channel layers.

3. The semiconductor device of claim 1, wherein the gate structure is disposed from an uppermost channel layer of the plurality of channel layers to a lowermost channel layer of the plurality of channel layers.

4. The semiconductor device of claim 1, wherein portions of the gate structure are further disposed between and alternately stacked with the respective ones of the plurality of channel layers.

5. The semiconductor device of claim 1, further comprising a first source/drain region disposed on a first side of the plurality of channel layers and a second source/drain region disposed on a second side of the plurality of channel layers, wherein a width of the gate structure is less than half of a distance from the first source/drain region to the second source/drain region.

6. The semiconductor device of claim 1, further comprising a first source/drain region disposed on a first side of the plurality of channel layers and a second source/drain region disposed on a second side of the plurality of channel layers, wherein the gate structure is closer to one of the first source/drain region and the second source/drain region.

7. The semiconductor device of claim 1, further comprising at least one source/drain region disposed on a side of the plurality of channel layers, wherein a portion of each of the respective ones of the plurality of channel layers is disposed on a side of the gate structure between the at least one source/drain region and the gate structure.

8. The semiconductor device of claim 7, further comprising a dielectric spacer disposed at least one of over and under at least part of the portion of each of the respective ones of the plurality of channel layers.

9. The semiconductor device of claim 1, wherein the gate structure is disposed through an inner portion of each of the respective ones of the plurality of channel layers.

10. The semiconductor device of claim 9, wherein outer portions of the respective ones of the plurality of channel layers are disposed on sides of the gate structure.

11. The semiconductor device of claim 1, further comprising:
an additional plurality of channel layers in an additional stacked configuration disposed on a side of the plurality of channel layers; and
a dielectric layer disposed between the plurality of channel layers and the additional plurality of channel layers;
wherein parts of respective ones of the plurality of channel layers and parts of respective ones of the additional plurality of channel layers contact the dielectric layer.

12. A semiconductor device comprising:
a plurality of channel layers alternately stacked with first portions of a gate structure; and
a second portion of the gate structure disposed through respective ones of the plurality of channel layers.

13. The semiconductor device of claim 12, wherein the second portion of the gate structure is surrounded on at least three sides by portions of the respective ones of the plurality of channel layers.

14. The semiconductor device of claim 12, wherein the second portion of the gate structure is disposed from an uppermost channel layer of the plurality of channel layers to a lowermost channel layer of the plurality of channel layers.

15. The semiconductor device of claim 12, further comprising at least one source/drain region disposed on a side of the plurality of channel layers, wherein a portion of each of the respective ones of the plurality of channel layers is disposed on a side of the second portion of the gate structure between the at least one source/drain region and the second portion of the gate structure.

16. The semiconductor device of claim 12, wherein the second portion of the gate structure is disposed through an inner portion of each of the respective ones of the plurality of channel layers.

17. A nanosheet transistor comprising:
a plurality of channel layers in a stacked configuration;
a gate structure disposed between respective first portions of the plurality of channel layers on a first side of the gate structure and respective second portions of the plurality of channel layers on a second side of the gate structure;
wherein the gate structure is disposed from an uppermost channel layer of the plurality of channel layers to a lowermost channel layer of the plurality of channel layers.

18. The nanosheet transistor of claim 17, wherein the gate structure is surrounded on at least three sides by respective ones of the plurality of channel layers.

19. The nanosheet transistor of claim 17, wherein portions of the gate structure are further disposed between and alternately stacked with respective ones of the plurality of channel layers.

20. The nanosheet transistor of claim 17, further comprising at least one source/drain region disposed on a side of the stacked configuration, wherein the respective first portions of the plurality of channel layers and the respective second portions of the plurality of channel layers are disposed between the at least one source/drain region and the gate structure.
